(19) United States
(12) Patent Application Publication
(10) Pub. No.: US 2025/0089450 A1
(43) Pub. Date: Mar. 13, 2025

(54) DISPLAY DEVICE AND MANUFACTURING METHOD THEREOF

(71) Applicant: Samsung Display Co., LTD., Yongin-si (KR)

(72) Inventor: KYONGTAE YU, Yongin-si (KR)

(73) Assignee: Samsung Display Co., LTD., Yongin-si (KR)

(21) Appl. No.: 18/600,773

(22) Filed: Mar. 11, 2024

(30) Foreign Application Priority Data
Sep. 7, 2023 (KR) 10-2023-0119108

(51) Int. Cl. H10K 59/12; H10K 59/121; H10K 59/124; H10K 59/131; H10K 71/10; H10K 71/50; H10K 85/10

(52) U.S. Cl. CPC H10K 59/1201; H10K 59/1213; H10K 59/124; H10K 59/131; H10K 71/191; H10K 71/50; H10K 85/10

(57) ABSTRACT

A display device according to an embodiment comprises an auxiliary electrode positioned on a substrate and transmitting a common voltage, an insulating layer positioned on the auxiliary electrode, a light emitting layer positioned on the insulating layer, and a common electrode positioned on the light emitting layer, the insulating layer has a through-opening disposed above the auxiliary electrode, the light emitting layer has a light emitting layer opening disposed above the auxiliary electrode and overlapping the through-opening, and the common electrode is electrically connected to the auxiliary electrode through the light emitting layer opening, and the through-opening is disposed within an edge of the light emitting layer opening in a plan view.

### CROSS-REFERENCE TO RELATED APPLICATION

This application claims priority to and the benefits of Korean Patent Application No. 10-2023-0119108 under 35 U.S.C. § 119 filed at the Korean Intellectual Property Office (KIPO) on Sep. 7, 2023, the entire contents of which are incorporated herein by reference.

### BACKGROUND

### 1. Technical Field

This disclosure relates to a display device and a method of manufacturing the same.

### 2. Description of the Related Art

Display devices such as liquid crystal displays (LCD) and organic light emitting diode displays (OLED displays) include a display panel including one or more pixels capable of displaying images.

Each pixel includes a pixel electrode that receives a data signal, one or more transistors and one or more capacitors that transmit the data signal to the pixel electrode, and a common electrode opposing the pixel electrode.

At least one layer may be located between the pixel electrode and the common electrode.

A common electrode can be formed across one or more pixels to transmit a constant voltage to each pixel.

### SUMMARY

As display devices become larger, power consumption due voltage drop of a common electrode may increase. Therefore, by forming an auxiliary electrode and electrically connecting the common electrode to the auxiliary electrode, the voltage drop of the voltage transmitted by the common electrode can be reduced or prevented.

The technical objectives to be achieved by the disclosure are not limited to those described herein, and other technical objectives that are not mentioned herein would be clearly understood by a person skilled in the art from the description of the disclosure.

Embodiments enable electrical connection between the common electrode and the auxiliary electrode by preventing the presence of a resistance layer between the auxiliary electrode and the common electrode, preventing the generation of dark spots by eliminating particle generation, and preventing an increase in dead space, which reduces the manufacturing cost of the display device and improves the yield.

A display device according to an embodiment includes an auxiliary electrode positioned on a substrate and transmitting a common voltage, an insulating layer positioned on the auxiliary electrode, a light emitting layer positioned on the insulating layer, and a common electrode positioned on the light emitting layer, wherein the insulating layer has a through-opening disposed above the auxiliary electrode, the light emitting layer has a light emitting layer opening disposed above the auxiliary electrode and overlapping the through-opening, and the common electrode is connected to the auxiliary electrode through the light emitting layer opening. They are electrically connected, and the through-opening is disposed within an edge of the light emitting layer opening in a plan view.

The display device may further include a common voltage line disposed on the substrate and transmitting the common voltage, and the auxiliary electrode may be electrically connected to the common voltage line.

The display device may include a plurality of pixels, each of the plurality of pixels includes a plurality of sub-pixels capable of displaying different colors, each of the plurality of sub-pixels includes a transistor and a light emitting diode, and the light emitting diode includes a pixel electrode, and it may include the light emitting layer and the common electrode.

The auxiliary electrode and the pixel electrode may be disposed on a same conductive layer and may include a same material.

The insulating layer may include a pixel opening that overlaps the pixel electrode.

A part of the auxiliary electrode overlapping the common voltage line may be electrically connected to the common voltage line through at least one opening of the insulating layer.

A planar shape of the light emitting layer opening may be circular, elliptical, or polygonal.

A method of manufacturing a display device according to an embodiment includes forming an auxiliary electrode on a substrate, forming a through-opening by stacking and patterning an insulating layer on the auxiliary electrode, and placing a mask pattern at a position overlapping the through-opening, a step of stacking a light emitting layer on the mask pattern and the insulating layer, removing the mask pattern and forming a light emitting layer opening in the light emitting layer, and forming a common electrode on the light emitting layer, wherein the common electrode is electrically connected to the auxiliary electrode through the light emitting layer opening.

The mask pattern may include an organic material including polyimide.

The positioning of the mask pattern at a position overlapping the through-opening may include forming the mask pattern on a master substrate.

The positioning of the mask pattern at a position overlapping the through-opening may include transferring the mask pattern formed on the master substrate to a transfer substrate, and transferring the mask pattern transferred to the transfer substrate onto the substrate.

The transfer substrate may include an electrostatic chuck.

The positioning of the mask pattern at a position overlapping the through-opening may include directly transferring the mask pattern formed on the master substrate onto the substrate.

The removing of the mask pattern may include transferring the mask pattern using an electrostatic chuck.

A width of the mask pattern may be smaller than a width of the through-opening.

A width of the mask pattern may be the same as a width of the through-opening.

A width of the mask pattern may be larger than a width of the through-opening.

The method may further include forming a common voltage line on the substrate, and the auxiliary electrode may be electrically connected to the common voltage line.

The method may further include forming a plurality of pixel electrodes on the substrate may be further comprised, wherein the auxiliary electrode and the plurality of pixel electrodes may be disposed on a same conductive layer and may include a same material.

The forming of the through-opening by patterning the insulating layer may include forming a pixel opening overlapping the plurality of pixel electrodes.

According to the embodiments, by ensuring that there is no resistance layer between the auxiliary electrode and the common electrode when they contact, it is possible to enable electrical connection between the common electrode and the auxiliary electrode, eliminate particle generation, prevent the occurrence of blind spots, prevent the increase of dead space, reduce the manufacturing cost of the display device, and improve yield.

### BRIEF DESCRIPTION OF THE DRAWINGS

FIG. 1 is a schematic plan view of an electrode layer and a common voltage line disposed in a pixel of a display area of a display device according to an embodiment.

FIG. 2 is a schematic plan view of pixels and auxiliary electrodes in a display area of a display device according to an embodiment.

FIG. 3 is a schematic plan view of an auxiliary electrode of a display device according to an embodiment.

FIG. 4 is a schematic cross-sectional view of the display device shown in FIG. 3 taken along line A1-A2 of FIG. 3.

FIG. 5 is a schematic cross-sectional view of a pixel of a display device according to an embodiment.

FIG. 6 is a schematic plan view of an auxiliary electrode of a display device according to an embodiment.

FIG. 7 is a schematic cross-sectional view of the display device shown in FIG. 6 taken along line B1-B2.

FIG. 8 is a schematic plan view of an auxiliary electrode of a display device according to an embodiment.

FIG. 9 is a schematic cross-sectional view of the display device shown in FIG. 8 taken along line C1-C2.

FIG. 10 is a schematic cross-sectional view of a display device in a process step of a method of manufacturing a display device according to an embodiment.

FIG. 11 to FIG. 13 are schematic diagrams showing the positions of mask patterns in process steps of the display device manufacturing method according to an embodiment.

FIG. 14 and FIG. 15 are schematic cross-sectional views of a display device in sequential process steps of a method of manufacturing a display device according to an embodiment.

FIG. 16 is a schematic diagram showing a mask pattern in a process step of a method of manufacturing a display device according to an embodiment.

FIG. 17 is a schematic diagram showing a mask pattern at a process stage of a method for manufacturing a display device according to an embodiment.

FIG. 18 and FIG. 19 are schematic cross-sectional views of a display device at sequential process steps in a method of manufacturing a display device according to an embodiment.

FIG. 20 and FIG. 21 are schematic cross-sectional views of a display device at sequential process steps in a method of manufacturing a display device according to an embodiment.

### DETAILED DESCRIPTION OF THE EMBODIMENTS

Hereinafter, with reference to the attached drawings, various embodiments of the disclosure will be described in detail so that those skilled in the art can easily implement the disclosure.

The disclosure may be implemented in many different forms and is not limited to the embodiments described herein.

In order to more clearly explain the disclosure, descriptions that are not relevant or that are repetitive may be omitted, and identical or similar components may be assigned the same reference numerals and/or reference characters throughout the specification.

In addition, the size and thickness of each component shown in the drawings may be shown arbitrarily for convenience of explanation, so the disclosure is not necessarily limited to that which is shown.

In the drawing, dimensions such as thickness may be exaggerated to more clearly illustrate various layers and regions.

When a part of a layer, membrane, region, or plate is said to be “above” or “on” another part, this includes not only cases where it is “directly above” another part, but also cases where there is another part in between.

Conversely, when a part is said to be “directly on” another part, it means that there is no other part in between.

Being “above” or “on” a reference part means being located above or below the reference part, and does not necessarily mean being located “above” or “on” it in the direction opposite to gravity.

Throughout the specification, when a part is said to “include,” “comprise,” or “have” a certain component, this means that it may further include other components rather than excluding other components, unless specifically stated to the contrary.

Throughout the specification, when reference is made to “on a plane” or “in a plan view,” this means when the target portion is viewed from above, and when reference is made to “in cross-section” or “in a cross-sectional view,” this means when a cross-section of the target portion is cut vertically and viewed from the side.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ÷30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

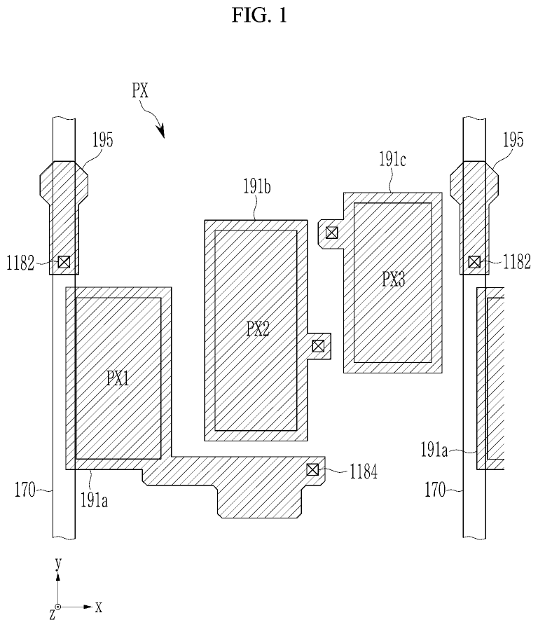

The structure of a display device according to an embodiment will be described with reference to FIG. 1 to FIG. 5.

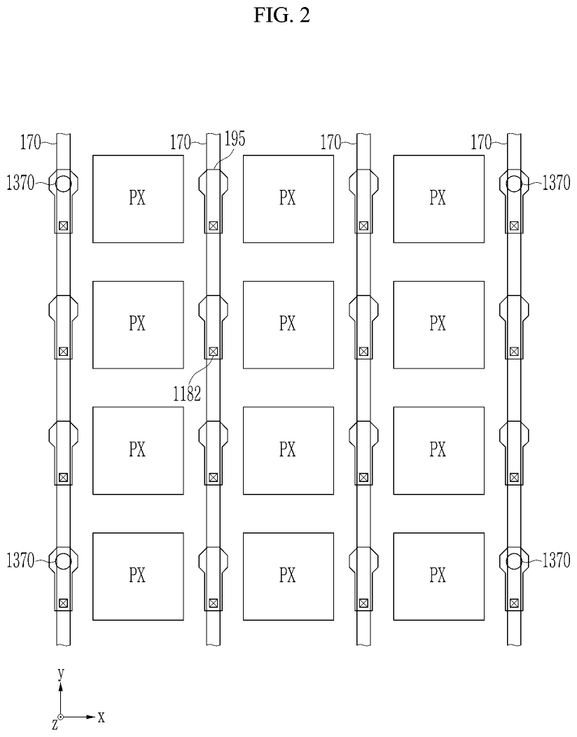

FIG. 1 is a schematic plan view of an electrode layer and a common voltage line located in a pixel of a display area of a display device according to an embodiment, and FIG. 2 is a schematic plan view of pixels and auxiliary pixels in a display area of a display device according to an embodiment.

Referring to FIG. 1 and FIG. 2, a display device according to an embodiment may include one or more pixels PX, which may be units capable of displaying an image.

The pixels PX may be arranged roughly in a matrix form on a plane as shown in FIG. 2, but the disclosure is not limited to this and may be arranged repeatedly according to various rules.

Referring to FIG. 1, each pixel PX may include one or more sub-pixels PX1, PX2, and PX3.

The sub-pixels PX1, PX2, PX3 included in each pixel PX may display light of different colors.

For example, the sub-pixels PX1, PX2, PX3 can display basic colors such as red, green, and blue.

The display device can display images of various colors by combining various luminances of different basic colors displayed by sub-pixels PX1, PX2, and PX3.

Each sub-pixel PX1, PX2, PX3 may include pixel electrodes 191a, 191b, 191c capable of receiving a data signal including luminance information of the light being displayed, and one or more transistors electrically connected thereto.

The pixel electrodes 191a, 191b, and 191c may be located in the same layer on the substrate, and may include the same material; the layer where the pixel electrodes 191a, 191b, and 191c are located may be called a pixel electrode layer.

Each pixel electrode 191a, 191b, 191c can be electrically connected to each transistor formed in each sub-pixel PX1, PX2, PX3 through an opening 1184, which is a hole formed in at least one insulating layer located between the substrate and the pixel electrode 191a, 191b, 191c.

A display device according to an embodiment may include one or more common voltage lines 170 and one or more auxiliary electrodes 195 that transmit a common voltage.

The common voltage line 170 may extend approximately in the y-direction.

The common voltage line 170 may be located for each of one or more pixels PX in the x-direction perpendicular to the y-direction.

FIG. 1 and FIG. 2 show an example in which one common voltage line 170 is located for each pixel PX in the x direction, but the disclosure is not limited thereto.

The auxiliary electrode 195 may be positioned one by one for each of one or two or more pixels PX in the x-direction or y-direction.

FIG. 1 and FIG. 2 show an example in which an auxiliary electrode 195 is formed for each pixel PX in each of the x-and y-directions, but the disclosure is not limited thereto.

The auxiliary electrode 195 may be located on a conductive layer different from the common voltage line 170 on the substrate.

At least a portion of each auxiliary electrode 195 may overlap the common voltage line 170 in the z-direction perpendicular to the x- and y-directions.

The part of the auxiliary electrode 195 overlapping the common voltage line 170 can be electrically connected to the common voltage line 170 through at least one opening 1182 of the insulating layer located between the common voltage line 170 and the auxiliary electrode 195.

Referring to FIG. 2, the light emitting layer opening 1370 may be located on some of the auxiliary electrodes 195 or all of the auxiliary electrodes 195 among the auxiliary electrodes 195.

The auxiliary electrode 195 overlapping the light emitting layer opening 1370 may be electrically connected to the lower common voltage line 170 through the opening 1182.

The auxiliary electrode 195 that does not overlap the light emitting layer opening 1370 may also be electrically connected to the common voltage line 170 through the opening 1182.

However, depending on embodiments, at least some of the auxiliary electrodes 195 that do not overlap the light emitting layer opening 1370 may not overlap the opening 1182.

The auxiliary electrode 195 and the pixel electrode layer where the pixel electrodes 191a, 191b, and 191c are located may be located on a same conductive layer, and may include a same conductive material, but the embodiments are not limited thereto.

The planar shape of the light emitting layer opening 1370 may be various, such as circular, elliptical, or polygonal.

In this embodiment, the description will focus on an embodiment in which the light emitting layer opening 1370 is circular, but the embodiments are not limited thereto.

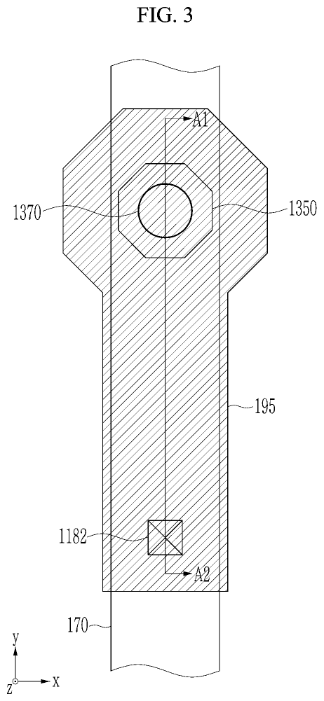

A detailed structure of a display device according to an embodiment will be described with reference to FIG. 3 to FIG. 5.

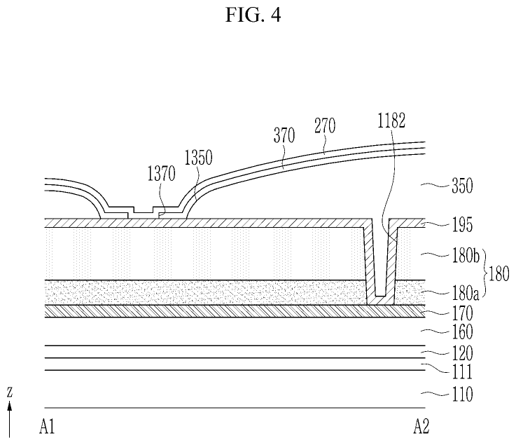

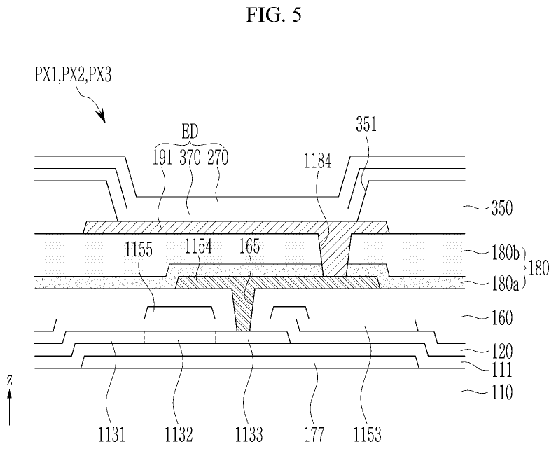

FIG. 3 is a schematic plan view of an auxiliary electrode of a display device according to an embodiment, FIG. 4 is a schematic cross-sectional view of the display device shown in FIG. 3 taken along line A1-A2, and FIG. 5 is a schematic cross-sectional view of one pixel of a display device according to an embodiment.

A display device according to an embodiment may include a substrate 110 that may include glass, quartz, or plastic such as polyimide, and a buffer layer 111, which may be an insulating layer, may be located on the substrate 110.

A first conductive layer including a light blocking pattern 177 may be positioned between the substrate 110 and the buffer layer 111.

A semiconductor layer including a channel region 1132 and conductive regions 1131 and 1133 located on sides (e.g., two or both sides) of the channel region 1132 may be located on the buffer layer 111.

The conductive region 1131 located on one side of one channel region 1132 may be a source region, and the conductive region 1133 located on the other side may be a drain region, and vice versa.

The source region and drain region may be referred to as a source electrode and a drain electrode, respectively.

A first insulating layer 120 may be located on the semiconductor layer.

A second conductive layer including a gate electrode 1155 and a lower electrode 1153 may be positioned on the first insulating layer 120.

The gate electrode 1155 may overlap the channel region 1132 in the z-direction.

The gate electrode 1155 may be electrically connected to the lower electrode 1153, and they may be formed as one body or integral with each other.

The channel region 1132, the conductive regions 1131 and 1133, and the gate electrode 1155 may together form a transistor.

A second insulating layer 160 may be positioned on the gate electrode 1155 and the lower electrode 1153.

A third conductive layer including an upper electrode 1154 and a common voltage line 170 may be positioned on the second insulating layer 160.

The upper electrode 1154 may form a capacitor by overlapping the lower electrode 1153 with the second insulating layer 160 therebetween.

The lower electrode 1153 may also overlap the light blocking pattern 177 with the first insulating layer 120 interposed therebetween.

The upper electrode 1154 may be electrically connected to the conductive region 1133 of the transistor through the opening 165 formed in the second insulating layer 160 and the first insulating layer 120.

A third insulating layer 180 may be positioned on the common voltage line 170 and the upper electrode 1154.

The third insulating layer 180 may include a first protective layer 180a and a second protective layer 180b.

The third insulating layer 180 may include one or more openings 1184 and one or more openings 1182 located on the common voltage line 170.

At least one of the first conductive layer, the second conductive layer, and the third conductive layer may include at least one of metal such as copper (Cu), aluminum (Al), magnesium (Mg), silver (Ag), gold (Au), platinum (Pt), palladium (metals including Pd), nickel (Ni), neodymium (Nd), iridium (Ir), molybdenum (Mo), tungsten (W), titanium (Ti), chromium (Cr), tantalum (Ta), etc., an alloy thereof, and/or a metal oxide such as indium tin oxide (ITO), and indium zinc oxide (IZO).

Each of the first conductive layer, the second conductive layer, and the third conductive layer may be made of a single layer or multiple layers.

For example, at least one of the first conductive layer, the second conductive layer, and the third conductive layer may have a multi-layer structure including a lower layer including titanium, a middle layer including copper, and an upper layer including ITO.

At least one of the buffer layer 111, the first insulating layer 120, the second insulating layer 160, and the third insulating layer 180 may be made of inorganic insulating material such as silicon nitride (SiNₓ), silicon oxide (SiOₓ), silicon nitride oxide (SiON), etc., and/or organic insulating material such as polyimide, acrylic polymer, or siloxane polymer.

The first protective layer 180a of the third insulating layer 180 may be made of an inorganic insulating material, and the second protective layer 180b may be made of an organic insulating material.

A fourth conductive layer including an auxiliary electrode 195 may be positioned on the third insulating layer 180.

The auxiliary electrode 195 may be electrically connected to the common voltage line 170 through the opening 1182.

One or more pixel electrodes 191 may be positioned on the third insulating layer 180.

The pixel electrode 191 may include one or more pixel electrodes 191a, 191b, and 191c shown in FIG. 1.

According to an embodiment, the pixel electrodes 191 and the auxiliary electrode 195 may be located on a same conductive layer—for example, the fourth conductive layer.

For example, the pixel electrode 191 and the auxiliary electrode 195 may include a same material and can be formed together in a same process.

In this case, the fourth conductive layer may include a transparent metal oxide such as indium tin oxide (ITO) or indium zinc oxide (IZO).

The fourth conductive layer may be made of multiple layers or a single layer, such as a triple layer in which a layer including ITO, a layer including silver (Ag), and a layer including ITO are sequentially stacked.

Depending on embodiments, the pixel electrode 191 and the auxiliary electrode 195 may be located in different conductive layers, and may include different conductive materials.

The pixel electrode 191 may be electrically connected to the upper electrode 1154 through the opening 1184.

A fourth insulating layer 350 may be positioned on the auxiliary electrode 195 and the pixel electrode 191.

The fourth insulating layer 350 may include an organic insulating material such as polyimide, polyamide, acrylic resin, benzocyclobutene, or phenol resin, or a silica-based inorganic insulating material.

The fourth insulating layer 350 may have a through-opening 1350 that overlaps the auxiliary electrode 195 in the z-direction, and a pixel opening 351 that overlaps the pixel electrode 191.

The through-opening 1350 may not overlap but be spaced apart from the opening 1182 of the third insulating layer 180 in the x-y plane view.

The x-y plane view or x-y plane image refers to a plan view, e.g., when the target portion is viewed from above in the z-direction.

The light emitting layer 370 may be located on the fourth insulating layer 350.

The light emitting layer 370 may include a low-molecular organic material or a high-molecular organic material such as poly 3,4-ethylenedioxythiophene (PEDOT).

The light emitting layer 370 may include one or more of a hole injection layer (HIL), a hole transporting layer (HTL), an electron transporting layer (ETL), and an electron injection layer (EIL). It may further include multiple layers.

The light emitting layer 370 may be located in the pixel opening 351, and may include a portion located on the fourth insulating layer 350.

At least a portion of the light emitting layer 370 may be formed through a deposition process.

The light emitting layer 370 may have a light emitting layer opening 1370 that overlaps the auxiliary electrode 195.

The light emitting layer opening 1370 may overlap at least a portion of the through-opening 1350 of the fourth insulating layer 350.

Referring to FIG. 3 and FIG. 4, the light emitting layer opening 1370 of the light emitting layer 370 according to an embodiment may be located within the edge of the through-opening 1350 of the fourth insulating layer 350.

A portion of the light emitting layer 370 may be located in the through-opening 1350 of the fourth insulating layer 350.

Depending on embodiments, a portion of the light emitting layer opening 1370 may overlap a portion of an edge of the through-opening 1350 of the fourth insulating layer 350.

At least a portion of the light emitting layer 370 may be located within the pixel opening 351 of the fourth insulating layer 350, and may be in contact with the pixel electrode 191.

A common electrode 270 is located on the light emitting layer 370.

The common electrode 270 may be formed of a single conductor across one or more pixels.

The common electrode 270 may be positioned entirely on the substrate 110.

The common electrode 270 may be electrically connected to the auxiliary electrode 195 through the light emitting layer opening 1370 of the light emitting layer 370.

The common electrode 270 is electrically connected to the common voltage line 170 through the auxiliary electrode 195, and can receive a common voltage.

The common electrode 270 may include a metal material including silver (Ag) or a transparent metal oxide such as indium tin oxide (ITO) or indium zinc oxide (IZO).

The pixel electrode 191, the light emitting layer 370, and the common electrode 270 of each sub-pixel PX1, PX2, and PX3 may together form a light emitting diode ED.

The pixel electrode 191 can be an anode, and the common electrode 270 can be a cathode.

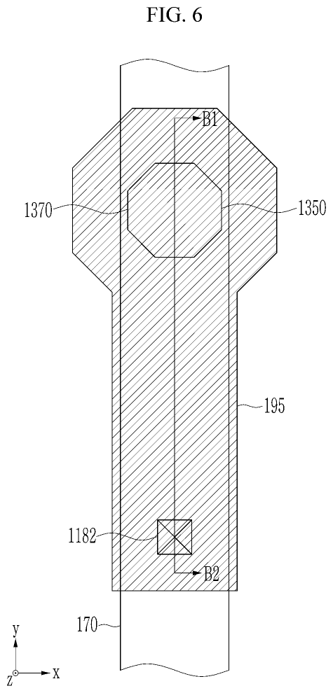

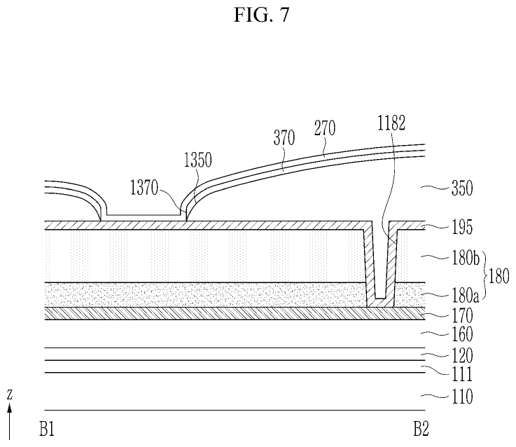

A display device according to an embodiment will be described with reference to FIG. 6 and FIG. 7 along with the previously described drawings.

FIG. 6 is a schematic plan view of an auxiliary electrode of a display device according to an embodiment, and FIG. 7 is a schematic cross-sectional view of the display device shown in FIG. 6 taken along line B1-B2.

Referring to FIG. 6 and FIG. 7, the display device according to the embodiment may be distinguishable from the display device shown in FIG. 1 to FIG. 5 described above at least in that the edge of the light emitting layer opening 1370 of the light emitting layer 370 is adjacent to the fourth insulating layer, and it may be aligned to substantially coincide with the edge of the through-opening 1350 of the fourth insulating layer 350.

Accordingly, the light emitting layer 370 may not be substantially located in the through-opening 1350 of the fourth insulating layer 350.

The side surface of the through-opening 1350 of the fourth insulating layer 350 may be inclined at an angle or may form a substantially flat surface together with the side surface of the light emitting layer opening 1370.

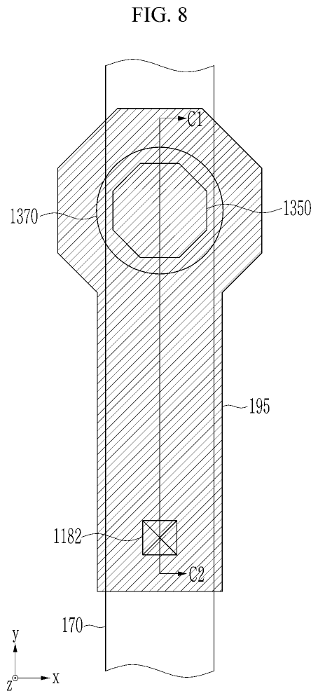

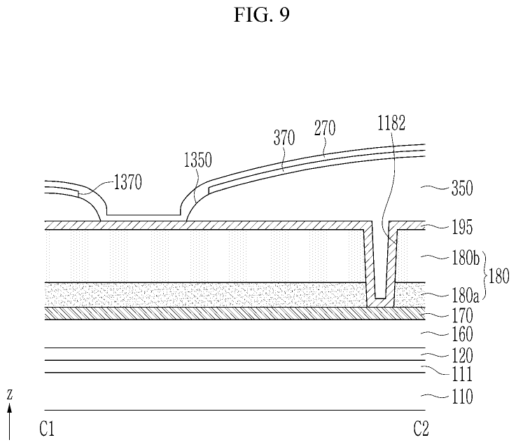

A display device according to an embodiment will be described with reference to FIG. 8 and FIG. 9 along with the previously described drawings.

FIG. 8 is a schematic plan view of an auxiliary electrode of a display device according to an embodiment, and FIG. 9 is a schematic cross-sectional view of the display device shown in FIG. 8 taken along line C1-C2.

Referring to FIG. 8 and FIG. 9, the display device according to the embodiment may be distinguishable from the display device shown in FIG. 1 to FIG. 5 described above at least in that the display device according to the embodiment is located inside the edge of the light emitting layer opening 1370 of the light emitting layer 370 on a planar surface, and the through-opening 1350 of the fourth insulating layer 350 inside the edge of the through-opening 1350.

The light emitting layer opening 1370 exposes at least a portion of the upper surface of the fourth insulating layer 350 around the through-opening 1350 of the fourth insulating layer 350, thereby exposing the fourth insulating layer 350 around the through-opening 1350, and at least a portion of the upper surface may not be covered by the light emitting layer 370.

The planar size of the light emitting layer opening 1370 may be larger than the planar size of the through-opening 1350 of the fourth insulating layer 350.

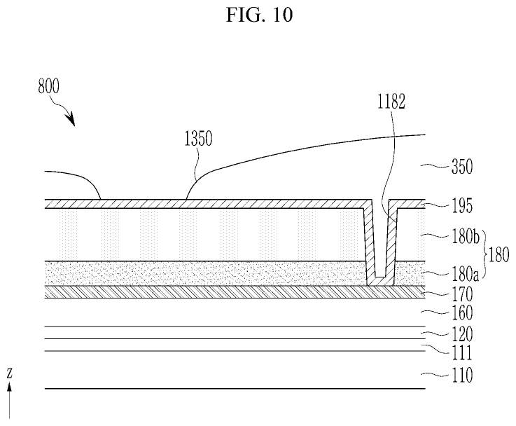

A method of manufacturing a display device according to an embodiment will be described with reference to FIG. 10 to FIG. 16 along with the previously described drawings.

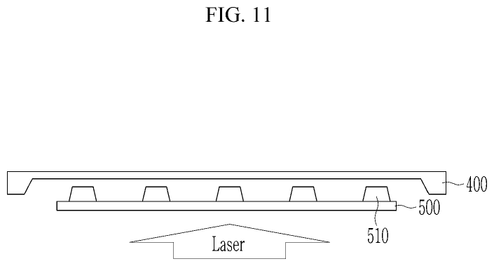

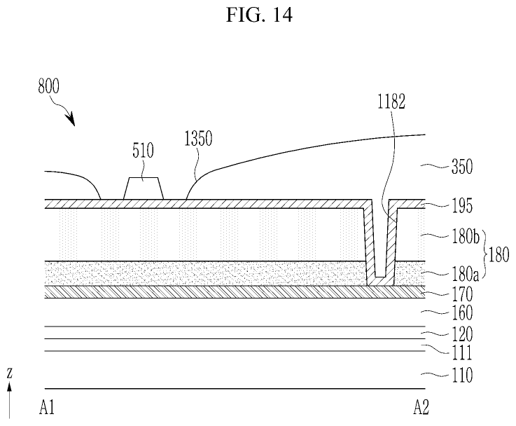

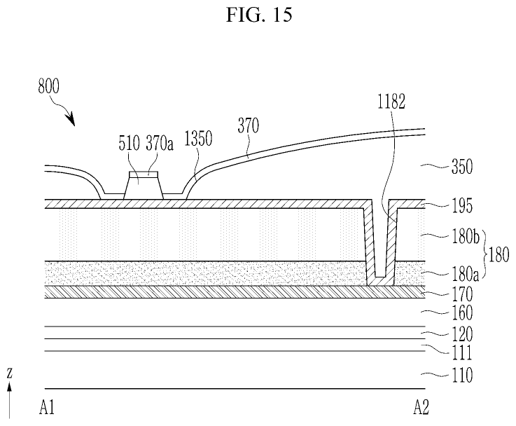

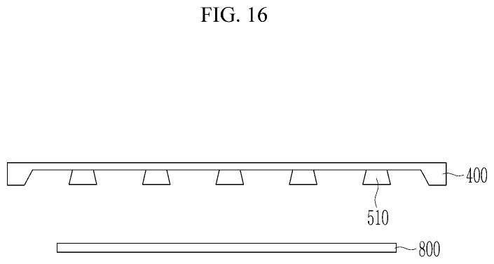

FIG. 10 is a schematic cross-sectional view of a display device at a process step in a method of manufacturing the display device according to an embodiment, FIG. 11 to FIG. 13 are schematic drawings showing the positions of mask patterns at process steps in a method of manufacturing the display device according to an embodiment, FIG. 14 and FIG. 15 are schematic cross-sectional views of the display device at sequential process steps in a method of manufacturing the display device according to an embodiment, and FIG. 16 is a schematic drawing showing the position of a mask pattern at a process step in a method of manufacturing the display device according to an embodiment.

Referring to FIG. 10, after forming multiple layers such as multiple common voltage lines 170, multiple auxiliary electrodes 195, etc. on the substrate 110, a fourth insulating layer 350 may be formed on the auxiliary electrode 195 and patterned to form a through hole 1350 to form a display device 800 of a process step.

Next, the light emitting layer 370 may be stacked on the fourth insulating layer 350.

At least some of the multiple layers included in the light emitting layer 370 may be laminated using a deposition process.

Next, referring to FIG. 11, a plurality of mask patterns 510 may be formed on a master substrate 500.

The mask pattern 510 may include an organic material such as PI, but is not limited to this and may include an organic material and an inorganic material, or it may include an inorganic material.

The mask pattern 510 may have a different upper and lower surface width in a cross-sectional view and may have an approximately trapezoidal cross-sectional shape.

FIG. 11 shows an example where the area of the lower surface of the mask pattern 510, which is closer to the master substrate 500, is larger than the area of the upper surface.

The position and spacing of the mask pattern 510 may correspond to the through-opening 1350 of the display device 800.

Next, the mask pattern 510 may be transferred to a transfer substrate 400.

In this step, the mask pattern 510 may be readily transferred by using a laser, and the transfer substrate 400 may include an electrostatic chuck.

This step can be carried out in the atmosphere.

After transferring the mask pattern 510, the master substrate 500 can be removed using a vacuum chuck.

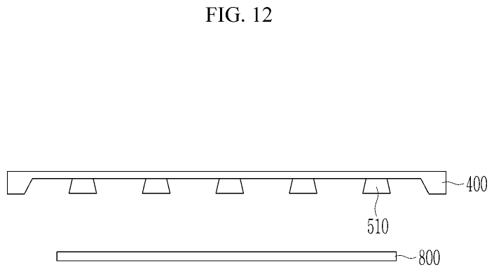

Next, referring to FIG. 12, the transfer substrate 400 with the mask pattern 510 attached may be aligned on the display device 800.

At this time, the mask pattern 510 may be aligned at a position corresponding to the through-opening 1350 of the display device 800 and at a position where the light emitting layer opening is to be formed.

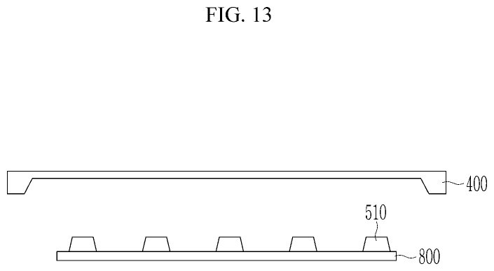

Next, referring to FIG. 13, the mask pattern 510 is transferred onto the display device 800.

Next, referring to FIG. 14, each mask pattern 510 transferred onto the display device 800 may be transferred and positioned at a location corresponding to each through-opening 1350 of the fourth insulating layer 350.

According to an embodiment, each mask pattern 510 may be located inside the edge of the corresponding through-opening 1350.

The width of the mask pattern 510 on an x-y plane may be smaller than the width of the through-opening 1350 on the x-y plane.

Next, referring to FIG. 15, a light emitting material for forming a light emitting layer 370 may be stacked on the display device 800 to which the mask pattern 510 has been transferred.

Lamination of light emitting materials can use a deposition process, an inkjet process, etc.

The stacked light emitting material layer may overlap the light emitting layer 370 and the mask pattern 510 described above and may include a light emitting material layer 370a deposited on the mask pattern 510.

Next, referring to FIG. 16, the mask pattern 510 of the display device 800 may be moved back toward the transfer substrate 400 using the transfer substrate 400 to remove it from the display device 800.

The transfer substrate 400 may include an electrostatic chuck.

This step can be carried out in a vacuum.

Then, the light emitting material layer 370a along with the removed mask pattern 510 may also be removed from the display device 800 to form the light emitting layer opening 1370 of the light emitting layer 370 as shown in FIG. 3 and FIG. 4 described above.

Due to the nature of this process, there may be no risk of generating residues or particles of the light emitting layer 370 around the edge of the light emitting layer opening 1370, so the edge of the light emitting layer opening 1370 can be formed neatly.

Next, a common electrode 270 may be formed on the display device 800.

The common electrode 270 may be electrically connected to the auxiliary electrode 195 through the light emitting layer opening 1370.

In other words, by forming a light emitting layer 370 using a mask pattern 510, it is possible to eliminate the resistance layer between the common electrode 270 and the auxiliary electrode 195, enabling electrical connection between the common electrode 270 and the auxiliary electrode 195.

In addition, in the case of other processes in which the light emitting layer is first laminated and then laser drilling of the light emitting layer is used to form the light emitting layer opening, there are no particles or light emitting layer residues that may be generated, so the occurrence of defects such as dark spots can be prevented.

Since there may be no need to create a separate space for laser drilling in the display area, an increase in dead space can be prevented, the manufacturing cost of the display device can be reduced, and the yield can be improved.

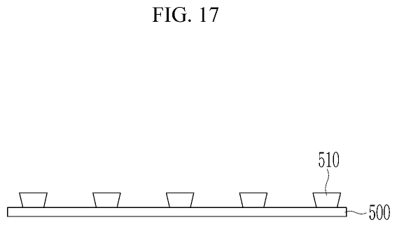

A method of manufacturing a display device according to an embodiment will be described with reference to FIG. 17 along with the previously described drawings.

FIG. 17 is a schematic diagram illustrating a mask pattern in one process step of a method of manufacturing a display device according to an embodiment.

Referring to FIG. 17, the manufacturing method of the display device according to an embodiment may be distinguishable from the manufacturing method of the display device according to the embodiment shown in FIG. 10 to FIG. 16 described above at least in that unlike the processes shown in FIG. 11 and FIG. 12, the mask pattern 510 formed on the master substrate 500 may be directly transferred onto the display device 800.

In this case, the mask pattern 510 formed on the master substrate 500 may have a different upper and lower width in a cross-sectional view, and the area of the lower surface closest to the master substrate 500 among the surfaces of the mask pattern 510 may be different, and it may be smaller than the area of the top surface.

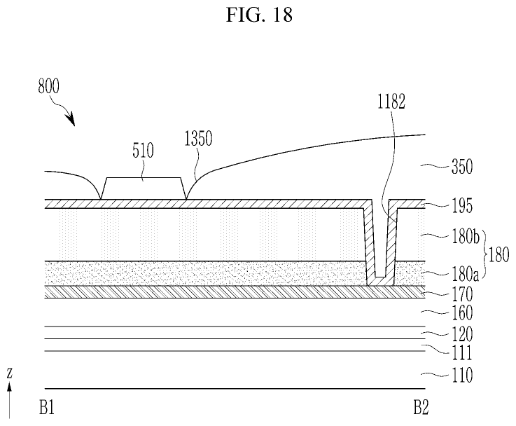

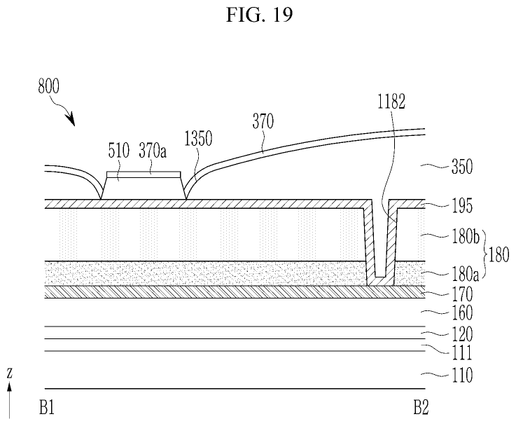

A method of manufacturing a display device according to an embodiment will be described with reference to FIG. 18 and FIG. 19 along with the previously described drawings.

FIG. 18 and FIG. 19 are schematic cross-sectional views of a display device at sequential process steps in a method of manufacturing a display device according to an embodiment.

Referring to FIG. 18 and FIG. 19, the manufacturing method of the display device according to this embodiment may be distinguishable from the manufacturing method of the display device according to the embodiment shown in FIG. 10 to FIG. 16 described above at least in that the edge of each mask pattern 510 transferred onto the display device 800 may be aligned to substantially coincide with the edge of the corresponding through-opening 1350.

The width of the mask pattern 510 on the x-y plane may be substantially the same as the width of the through-opening 1350 on the x-y plane.

In case that the light emitting material layer 370a along with the removed mask pattern 510 is removed from the display device 800, the light emitting layer opening 1370 of the light emitting layer 370 as shown in FIG. 6 and FIG. 7 described above can be formed.

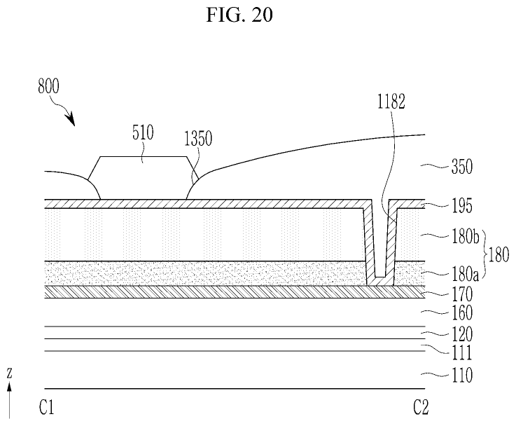

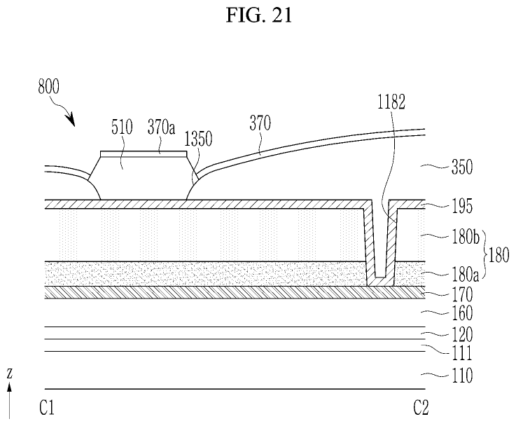

A method of manufacturing a display device according to an embodiment will be described with reference to FIG. 20 and FIG. 21 along with the previously described drawings.

FIG. 20 and FIG. 21 are schematic cross-sectional views of a display device at sequential process steps in a method of manufacturing a display device according to an embodiment.

Referring to FIG. 20 and FIG. 21, the manufacturing method of the display device according to this embodiment may be distinguishable from the manufacturing method of the display device according to the embodiment shown in FIG. 10 to FIG. 16 described above at least in that an edge of the through-opening corresponding to the edge of each mask pattern 510 may be transferred onto the display device 800.

The width of the mask pattern 510 on the x-y plane may be greater than the width of the through-opening 1350 on the x-y plane.

In case that the light emitting material layer 370a along with the removed mask pattern 510 is removed from the display device 800, the light emitting layer opening 1370 of the light emitting layer 370 as shown in FIG. 8 and FIG. 9 described above can be formed.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
an auxiliary electrode disposed on a substrate and transmitting a common voltage;
an insulating layer disposed on the auxiliary electrode;
a light emitting layer disposed on the insulating layer, and
a common electrode disposed on the light emitting layer, wherein
the insulating layer has a through-opening disposed above the auxiliary electrode,
the light emitting layer is disposed above the auxiliary electrode and has a light emitting layer opening that overlaps the through-opening,
the common electrode is electrically connected to the auxiliary electrode through the light emitting layer opening, and
the through-opening is disposed within an edge of the light emitting layer opening in a plan view.

2. The display device of claim 1, further comprising:
a common voltage line disposed on the substrate and transmitting the common voltage,
wherein the auxiliary electrode is electrically connected to the common voltage line.

3. The display device of claim 1, wherein
the display device comprises a plurality of pixels,
each of the plurality of pixels comprises a plurality of sub-pixels capable of displaying different colors,
each of the plurality of sub-pixels comprises a transistor and a light emitting diode, and
the light emitting diode comprises a pixel electrode, the light emitting layer, and the common electrode.

4. The display device of claim 3, wherein the auxiliary electrode and the pixel electrode are disposed on a same conductive layer and comprise a same material.

5. The display device of claim 3, wherein the insulating layer comprises a pixel opening that overlaps the pixel electrode.

6. The display device of claim 1, wherein a part of the auxiliary electrode overlapping the common voltage line is electrically connected to the common voltage line through at least one opening of the insulating layer.

7. The display device of claim 1, wherein a planar shape of the light emitting layer opening is circular, elliptical, or polygonal.

8. A method of manufacturing a display device, comprising:
forming an auxiliary electrode on a substrate,
forming a through-opening by laminating and patterning an insulating layer on the auxiliary electrode,
positioning a mask pattern at a position overlapping the through-opening,
laminating a light emitting layer on the mask pattern and the insulating layer,
removing the mask pattern and forming a light emitting layer opening in the light emitting layer, and
forming a common electrode on the light emitting layer,
wherein the common electrode is electrically connected to the auxiliary electrode through the light emitting layer opening.

9. The method of manufacturing a display device of claim 8, wherein the mask pattern comprises an organic material including polyimide.

10. The method of manufacturing a display device of claim 8, wherein the positioning of the mask pattern at a position overlapping the through-opening comprises forming the mask pattern on a master substrate.

11. The method of manufacturing a display device of claim 10, wherein the positioning of the mask pattern at a position overlapping the through-opening comprises:
transferring the mask pattern formed on the master substrate to a transfer substrate, and
transferring the mask pattern transferred to the transfer substrate onto the substrate.

12. The method of manufacturing a display device of claim 11, wherein the transfer substrate comprises an electrostatic chuck.

13. The method of manufacturing a display device of claim 10, wherein the positioning of the mask pattern at a position overlapping the through-opening comprises transferring the mask pattern formed on the master substrate directly onto the substrate.

14. The method of manufacturing a display device of claim 8, wherein the removing of the mask pattern comprises transferring the mask pattern using an electrostatic chuck.

15. The method of manufacturing a display device of claim 8, wherein a width of the mask pattern is smaller than a width of the through-opening.

16. The method of manufacturing a display device of claim 8, wherein a width of the mask pattern is equal to a width of the through-opening.

17. The method of manufacturing a display device of claim 8, wherein a width of the mask pattern is greater than a width of the through-opening.

18. The method of manufacturing a display device of claim 8, further comprising:
forming a common voltage line on the substrate,
wherein the auxiliary electrode is electrically connected to the common voltage line.

19. The method of manufacturing a display device of claim 8, further comprising:
forming a plurality of pixel electrodes on the substrate,
wherein the auxiliary electrode and the plurality of pixel electrodes are disposed on a same conductive layer and comprise a same material.

20. The method of manufacturing a display device of claim 19, wherein the forming of the through-opening by patterning the insulating layer comprises forming a pixel opening overlapping the plurality of pixel electrodes.
